(19) United States
(12) Patent Application Publication
(10) Pub. No.: US 2026/0182109 A1
(43) Pub. Date: Jun. 25, 2026

(54) DISPLAY DEVICE, ELECTRONIC DEVICE INCLUDING THE SAME, AND MANUFACTURING METHOD OF THE SAME

(71) Applicant: Samsung Display Co., LTD., Yongin-si (KR)

(72) Inventors: Gwangmin CHA, Yongin-si (KR); YEONGWOO KWON, Yongin-si (KR); Si Kwang KIM, Yongin-si (KR); Jin-Su BYUN, Yongin-si (KR); Yang-Ho JUNG, Yongin-si (KR)

(21) Appl. No.: 19/305,153

(22) Filed: Aug. 20, 2025

(30) Foreign Application Priority Data
Dec. 20, 2024 (KR) 10-2024-0193289

(51) Int. Cl. H10H 29/37; H10H 29/01

(52) U.S. Cl. CPC H10H 29/37; H10H 29/012

(57) ABSTRACT

A display device includes a substrate, a plurality of first electrodes disposed on the substrate, a pixel insulating layer disposed on the first electrode, where a pixel opening is defined through the pixel insulating layer, a partition wall disposed on the pixel insulating layer, a light emitting layer disposed on the first electrode and the pixel insulating layer, a sloper disposed on the pixel insulating layer to be adjacent to a side surface of the partition wall, and a second electrode disposed on the light emitting layer and the partition wall, where an inclination angle of the side surface of the partition wall with respect to an upper surface of the substrate is about 60° or greater and about 90° or less, and an inclination angle of the side surface of the sloper with respect to the upper surface of the substrate is about 45° or less.

This application claims priority to Korean Patent Application No. 10-2024-0193289, filed on Dec. 20, 2024, and all the benefits accruing therefrom under 35 U.S.C. § 119, the content of which in its entirety is herein incorporated by reference.

### BACKGROUND

### (a) Field

The present disclosure relates to a display device, an electronic device including the display device, and a manufacturing method of the display device.

### (b) Description of the Related Art

With the advance of an information-oriented society, there is increasing demand for display devices capable of displaying images in various ways. The display device may be a flat panel display device, such as a liquid crystal display device, a field emission display device, a light emitting display device, or the like.

### SUMMARY

In a manufacturing process of light emitting display devices, although a fine metal mask (FMM) is often used as a technology for depositing a light emitting layer on a substrate, using a FMM may increase manufacturing costs, so a technology that minimizes the use of masks is desired.

Embodiments provide a high-resolution display device, an electronic device including the high-resolution display device, and a manufacturing method of the high-resolution display device in which a resistance problem is improved and a deterioration problem of a light emitting device is improved.

A display device according to an embodiment includes a substrate, a plurality of first electrodes disposed on the substrate, a pixel insulating layer disposed on the first electrode, where a pixel opening is defined through the pixel insulating layer, a partition wall disposed on the pixel insulating layer, a light emitting layer disposed on the first electrode and the pixel insulating layer, a sloper disposed on the pixel insulating layer to be adjacent to a side surface of the partition wall, and a second electrode disposed on the light emitting layer and the partition wall, where an inclination angle of the side surface of the partition wall with respect to an upper surface of the substrate is about 60° or greater and about 90° or less, and an inclination angle of a side surface of the sloper with respect to the upper surface of the substrate is about 45° or less.

In an embodiment, a side surface of the light emitting layer may contact the side surface of the partition wall.

In an embodiment, a width of the partition wall may be in a range of about 1.5 micrometers (μm) to about 3 μm.

In an embodiment, a height of the partition wall may be in a range of about 1 μm to about 3 μm.

In an embodiment, the sloper may cover the side surface of the partition wall and extend along an edge of the partition wall in a plan view.

In an embodiment, a width of the sloper in the plan view may be about 2 μm or less.

In an embodiment, the sloper may be disposed on the light emitting layer and overlap an edge of the light emitting layer in the plan view.

In an embodiment, the display device according to an embodiment may further include a sacrificial layer disposed between the light emitting layer and the sloper.

In an embodiment, the sacrificial layer may be in contact with the side surface of the partition wall.

In an embodiment, the light emitting layer may include a first light emitting layer including a portion disposed in the pixel opening, and the sacrificial layer is disposed between the sloper and the first light emitting layer.

In an embodiment, the light emitting layer may include a first light emitting layer including a portion disposed in the pixel opening and a second light emitting layer not overlapping the pixel opening, and the sacrificial layer may be disposed between the sloper and the second light emitting layer.

In an embodiment, the second electrode may be in contact with the light emitting layer, an upper surface of the partition wall, and the side surface of the sloper.

In an embodiment, the pixel insulating layer may overlap an edge of the first electrode in a plan view.

In an embodiment, the pixel insulating layer may overlap an entire portion of the partition wall in the plan view.

In an embodiment, the pixel insulating layer may overlap an entire portion of the sloper in the plan view.

In an embodiment, the width of the pixel insulating layer in the plan view may be about 5 μm or less.

A manufacturing method of a display device according to an embodiment includes preparing a substrate, forming a plurality of first electrodes on the substrate, forming a pixel insulating layer on the first electrode, where a pixel opening is formed through the pixel insulating layer, forming a partition wall on the pixel insulating layer, forming a first light emitting layer on the first electrode and the pixel insulating layer, forming a sloper on the partition wall to contact a side surface of the partition wall, and forming a second electrode on the first light emitting layer and the partition wall, where an inclination angle of the side surface of the partition wall with respect to an upper surface of the substrate is about 60° or greater and about 90° or less, and an inclination angle of the side surface of the sloper with respect to the upper surface of the substrate is about 45° or less.

In an embodiment, the substrate may include a first light emitting area and a second light emitting area, and after the forming the first light emitting layer and before the forming the sloper, the manufacturing method of the display device may further include laminating a first sacrificial layer on the first light emitting layer, removing portions of the first sacrificial layer and the first light emitting layer in a region excluding an inside of the partition wall surrounding the first light emitting area, laminating a second light emitting layer on an entire surface of the substrate, laminating a second sacrificial layer on the second light emitting layer, and removing portions of the second sacrificial layer and the second light emitting layer disposed in a region excluding an inside of the partition wall surrounding the second light emitting area.

In an embodiment, the manufacturing method of the display device according to an embodiment may further include removing portions of the first sacrificial layer and the second sacrificial layer, which do not overlap the sloper, to expose the first light emitting layer and the second light emitting layer.

In an embodiment, the substrate may include a first light emitting area and a second light emitting area, and after the forming the first light emitting layer and before the forming the sloper, the manufacturing method of the display device may further include laminating the first sacrificial layer on the first light emitting layer, and after the forming of the sloper, the manufacturing method of the display device may further include removing portions of the first sacrificial layer and the first light emitting layer in the second light emitting area, laminating the second light emitting layer on the entire surface of the substrate, laminating the second sacrificial layer on the second light emitting layer, and removing portions of the second sacrificial layer and the second light emitting layer in the first light emitting area.

An electronic device according to an embodiment includes a display device and a processor, where the display device includes a substrate, a plurality of first electrodes disposed on the substrate, a pixel insulating layer disposed on the first electrode, where a pixel opening is defined through the pixel insulating layer, a partition wall disposed on the pixel insulating layer, a light emitting layer disposed on the first electrode and the pixel insulating layer, a sloper disposed on the pixel insulating layer to be adjacent to a side surface of the partition wall, and a second electrode disposed on the light emitting layer and the partition wall, where an inclination angle of the side surface of the partition wall with respect to an upper surface of the substrate is about 60° or great and about 90° or less, and an inclination angle of the side surface of the sloper with respect to the upper surface of the substrate is about 45° or less.

A display device according to an embodiment may implement high resolution without using a fine metal mask when laminating a light emitting layer, effectively prevent deterioration of the light emitting layer without using a separate etching process for patterning the light emitting layer, and improve the problem of increased resistance of the second electrode of the light emitting device by not causing a short circuit.

In addition, the display device according to an embodiment may effectively prevent problem of moisture absorption or oxygen penetration even during an outdoor exposure process, so the problem of deterioration of the light emitting device is improved, enabling the implementation of a stable display device.

### BRIEF DESCRIPTION OF THE DRAWINGS

FIG. 1 is a schematic perspective view illustrating a state of use of a display device according to an embodiment.

FIG. 2 is a top plan view illustrating a portion of a display area of a display device according to an embodiment.

FIG. 3 is a cross-sectional view illustrating a portion of a display area in a display device according to an embodiment.

FIGS. 4 to 18 are cross-sectional views sequentially illustrating a manufacturing process of a display device according to an embodiment.

FIG. 19 is a cross-sectional view illustrating a portion of a display area in a display device according to an embodiment.

FIG. 20 is a block diagram of an electronic device according to an embodiment.

FIG. 21 is a schematic diagram of an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

The drawings and description are to be regarded as illustrative in nature and not restrictive, and like reference numerals designate like elements throughout the specification.

The size and thickness of each constituent element in the drawings are arbitrarily illustrated for better understanding and ease of description, but the following embodiments are not limited thereto. In the drawings, the thicknesses of layers and regions are exaggerated for clarity. In the drawings, the thicknesses of some layers and regions may be exaggerated for ease of description.

It should be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” in a direction opposite to gravity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In addition, the phrase “in a plan view” means a view from a position above the object (e.g., from the top), and the phrase “in a cross-section” means a view of a cross-section of the object which is vertically cut from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

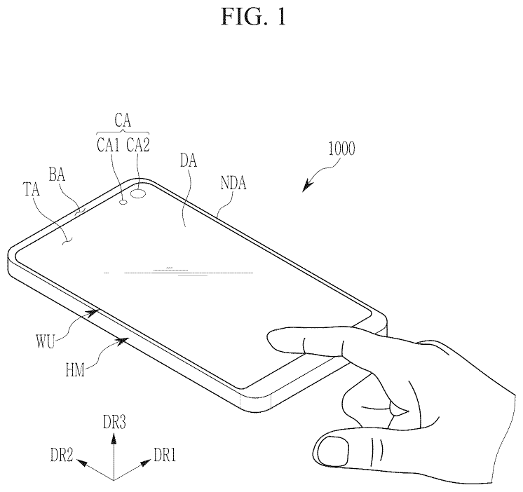

Referring to FIG. 1, a display device according to an embodiment will be described. FIG. 1 is a schematic perspective view illustrating a state of use of a display device according to an embodiment.

Referring to FIG. 1, a display device 1000 according to an embodiment is a device that displays videos or still images, and for convenience of description, the display device 1000 is illustrated as being used in a smartphone.

The display device 1000 may display images in a third direction DR3 on a display surface parallel to each of a first direction DR1 and a second direction DR2. Here, the third direction DR3 may be a thickness direction of the display device 1000. The display surface for displaying images may correspond to a front surface of the display device 1000, and may correspond to a front surface of a cover window WU. The images may include still images as well as videos.

In an embodiment, front surfaces (or upper surfaces) and rear surfaces (or lower surfaces) of respective members may be defined with reference to the direction in which the image is displayed. The front surface and the rear surface may oppose each other in the third direction DR3, and normal directions of the front surface and the rear surface may be parallel to the third direction DR3. The separation distance in the third direction DR3 between the front surface and rear surface of each member may correspond to the thickness of the corresponding member in the third direction DR3 of the display panel.

The display device 1000 according to an embodiment may sense a user's input applied from the outside (see hand in FIG. 1). The user's input may include various types of external inputs such as parts of the user's body, light, heat, or pressure. In an embodiment, the user's input is shown with the user's hand applied to the front surface. However, the present disclosure is not limited thereto and may be provided in various forms. Additionally, the display device 1000 may sense the user's input applied to various locations such as the side surface or rear surface of the display device 1000 depending on the structure.

The display device 1000 according to an embodiment may include the cover window WU, a housing HM, a display panel, an optical member, and an optical element. In an embodiment, the cover window WU and the housing HM may be combined to configure the exterior of the display device 1000.

The cover window WU may include an insulating panel. In an embodiment, for example, the cover window WU may include or be made of glass, plastic, or a combination thereof.

The front surface of the cover window WU may define the front surface of the display device 1000. A transmission area TA of the cover window WU may be an optically transparent area. In an embodiment, for example, the transmission area TA may be an area with a visible ray transmittance of about 90% or greater.

A blocking area BA of the cover window WU may define a shape (or a planar shape) of the transmission area TA. The blocking area BA may be adjacent to the transmission area TA and surround the transmission area TA. The blocking area BA may be an area with relatively low light transmittance compared to the transmission area TA. The blocking area BA may include an opaque material that blocks light. The blocking area BA may have a predetermined color. The blocking area BA may be defined by a bezel layer provided separately from a transparent substrate defining the transmission area TA, or by an ink layer formed by inserting or coloring the transparent substrate.

The display device 1000 may include a front surface including a display area DA and a non-display area NDA. The display area DA may be an area where pixels operate and emit light in response to electrical signals. In an embodiment, the display area DA is an area where an image is displayed including a pixel, and at the same time, an area where a touch sensor is positioned above the pixel in the third direction DR3 to sense an external input. The display area DA may include a plurality of pixels, each pixel including at least one light emitting device and a pixel circuit that generates and transmits light emitting current to the light emitting device.

The transmission area TA of the cover window WU may at least partially overlap the display area DA of the display device 1000. Accordingly, the user may view the image through the transmission area TA or provide external input based on the image. The area where the image is displayed and the area where external input is sensed within the display area DA may be separated.

The non-display area NDA of the display device 1000 may at least partially overlap the blocking area BA of the cover window WU in the third direction DR3 (or in a plan view). The non-display area NDA may be an area covered by the blocking area BA. The non-display area NDA may be adjacent to the display area DA and may surround at least a portion of the display area DA. The non-display area NDA does not display images, and a driving circuit or driving wiring may be positioned to drive the display area DA.

The display device 1000 according to an embodiment may include a component area CA, and specifically, may include a first component area CA1 and a second component area CA2. The first component area CA1 and the second component area CA2 may be at least partially surrounded by the display area DA. The first component area CA1 and the second component area CA2 are shown as being spaced apart, but are not limited thereto and may be at least partially connected. The first component area CA1 and the second component area CA2 may be areas where components utilizing infrared rays, visible rays, sound, etc. are positioned thereunder.

The first component area CA1 may include a transparent portion that is transparent to light and/or sound and a display portion that includes a plurality of pixels. The transparent portion is positioned between adjacent pixels and is formed of a layer through which light and/or sound may pass. The transparent portion may be positioned between adjacent pixels, and depending on the embodiments, a non-transparent layer, such as a light blocking member, may overlap the first component area CA1. The number of pixels per unit area (hereinafter, also referred to as resolution) of pixels included in the display area DA (hereinafter, also referred to as normal pixels) and the number of pixels per unit area of pixels included in the first component area CA1 (hereinafter, also referred to as first component pixels) may be the same as each other.

The second component area CA2 may include an area (hereinafter also referred to as a light transmitting area) formed of (or defined by) a transparent layer that allows light to pass therethrough, and the light transmitting area does not have a conductive layer or a semiconductor layer positioned thereon, and may have a structure that does not block light by including an opening where a layer including a light blocking material—for example, a pixel defining film and/or a light blocking member—overlaps a position corresponding to the second component area CA2 in the third direction DR3. The number of pixels per unit area of pixels included in the second component area CA2 (hereinafter also referred to as second component pixels) may be smaller than the number of pixels per unit area of normal pixels included in the display area DA. As a result, the resolution of the second component pixels may be lower than the resolution of normal pixels.

The housing HM may be coupled with the cover window WU. The cover window WU may be positioned on the front surface of the housing HM. The housing HM may be coupled with the cover window WU to provide a predetermined accommodation space. The display device 1000 and an optical element ES may be accommodated in a predetermined accommodation space provided between the housing HM and the cover window WU.

The housing HM may include a material having relatively high stiffness. In an embodiment, for example, the housing HM may include a plurality of frames and/or plates made of glass, plastic, or metal, or a combination thereof. The housing HM may reliably protect the components of the display device 1000 accommodated in the internal space from external impact.

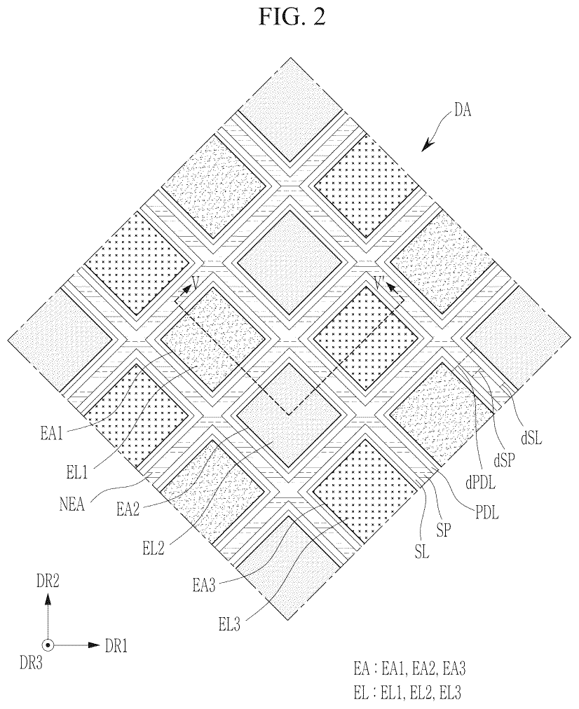

Hereinafter, a display area of a display device according to an embodiment will be described with reference to FIG. 2. FIG. 2 is a top plan view illustrating a portion of a display area of a display device according to an embodiment.

Referring to FIG. 2, the display area DA of the display device according to an embodiment may include a plurality of pixels, and each pixel may include a light emitting area EA, which is an area where light is substantially emitted. The light emitting area EA may include a first light emitting area EA1, a second light emitting area EA2, and a third light emitting area EA3 that display different colors from each other. In an embodiment, for example, the light emitting area EA may include the first light emitting area EA1 that emits red light, the second light emitting area EA2 that emits blue light, and the third light emitting area EA3 that emits green light.

The first light emitting area EA1, the second light emitting area EA2, and the third light emitting area EA3 may be repeatedly positioned in the first direction DR1 and the second direction DR2. In an embodiment, for example, as shown in FIG. 2, the first light emitting area EA1, the third light emitting area EA3, and the second light emitting area EA2 may be repeatedly positioned in the first direction DR1. Additionally, each of the first light emitting area EA1, the second light emitting area EA2, and the third light emitting area EA3 may be repeatedly positioned in one column in the second direction DR2. However, the arrangement form of the pixels is not limited to this arrangement form, and the first light emitting area EA1, the second light emitting area EA2, and the third light emitting area EA3 may be positioned in various forms. The arrangement of the light emitting areas EA1, EA2, and EA3 may be varied. In an embodiment, for example, the first light emitting area EA1, the second light emitting area EA2, and the third light emitting area EA3 may be positioned as a PenTile™ type or a Diamond PenTile™ type.

Referring to FIG. 2, the display device according to an embodiment may include a non-light emitting area NEA that does not overlap the first light emitting area EA1, the second light emitting area EA2, or the third light emitting area EA3 in the display area DA. The non-light emitting area NEA is positioned around the first light emitting area EA1, the second light emitting area EA2, and the third light emitting area EA3. The non-light emitting area NEA may be positioned between the adjacent first light emitting area EA1, second light emitting area EA2, and third light emitting area EA3.

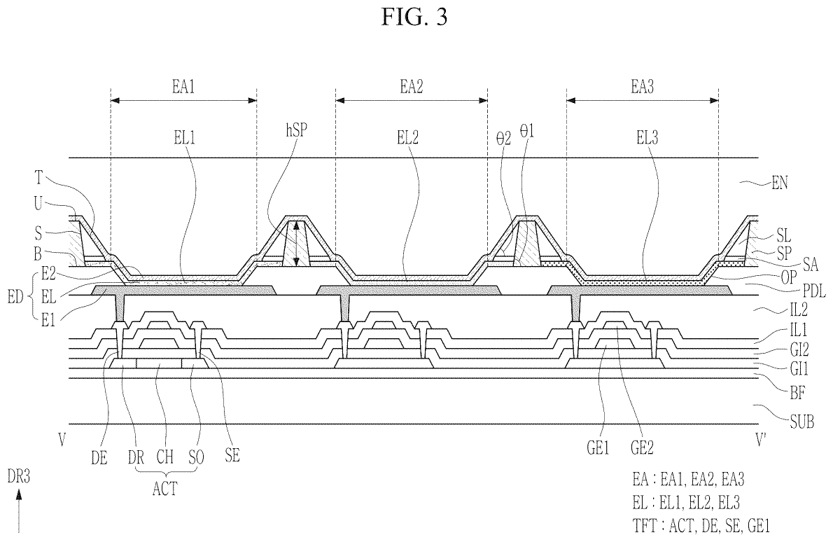

Hereinafter, the display area of the display device according to an embodiment will be described with reference to FIG. 3 together with FIG. 2. FIG. 3 is a cross-sectional view illustrating a portion of a display area in a display device according to an embodiment.

Referring to FIG. 3, a substrate SUB may include a material having rigid characteristics (or high rigidity), such as glass, or a flexible material that can be bent, such as plastic or polyimide.

A buffer layer BF may be positioned on the substrate SUB. The buffer layer BF may planarize the surface of the substrate SUB and block the penetration of impure elements. The buffer layer BF may include an inorganic material—for example, an inorganic insulating material such as silicon nitride (SiNx), silicon oxide (SiOx), silicon oxynitride (SiOxNy), or the like. In an embodiment, the buffer layer BF may be a single-layer or multi-layer structure including at least one selected from the above-listed inorganic insulating materials.

A semiconductor layer ACT may be positioned on the buffer layer BF. The semiconductor layer ACT may include any one of amorphous silicon, polycrystalline silicon, and an oxide semiconductor. In an embodiment, for example, the semiconductor layer ACT may include low-temperature polysilicon (LTPS) or an oxide semiconductor including at least one selected from zinc (Zn), indium (In), gallium (Ga), tin (Sn), and a combination (e.g., mixture) thereof. In an embodiment, for example, the semiconductor layer ACT may include indium-gallium-zinc oxide (IGZO). The semiconductor layer ACT may include a channel region CH, a source region SO, and a drain region DR, which are distinguished depending on whether or not they are doped with impurities. The source region SO and the drain region DR may have conductive characteristics corresponding to the conductor.

A first gate insulating film GI1 may be positioned on the semiconductor layer ACT. The first gate insulating film GI1 may cover the semiconductor layer ACT and the substrate SUB. The first gate insulating film GI1 may include an inorganic insulating material such as silicon nitride (SiNx), silicon oxide (SiOx), or silicon oxynitride (SiOxNy). The first gate insulating film GI1 may be a single-layer or multi-layer structure including the above inorganic insulating material.

A gate electrode GE1 may be positioned on the first gate insulating film GI1. The gate electrode GE1 may include a metal or metal alloy such as copper (Cu), molybdenum (Mo), aluminum (Al), silver (Ag), chromium (Cr), tantalum (Ta), or titanium (Ti). The gate electrode GE1 may be a single-layer or multi-layer structure. The region overlapping the gate electrode GE1 in a plan view among the semiconductor layers ACT may be the channel region CH. As used herein, “in a plan view” may refer to a view seen from a direction perpendicular to a plane parallel to the first direction DR1 and the second direction DR2 (that is, a view from the third direction DR3).

A second gate insulating film GI2 may be positioned on the gate electrode GE1. The second gate insulating film GI2 may include an inorganic insulating material such as silicon nitride (SiNx), silicon oxide (SiOx), or silicon oxynitride (SiOxNy). The second gate insulating film GI2 may be a single-layer or multi-layer structure including at least one selected from the above-listed inorganic insulating materials.

A capacitor electrode GE2 may be positioned on the second gate insulating film GI2. The capacitor electrode GE2 overlaps the gate electrode GE1 in the third direction DR3 (or a thickness direction of the substrate SUB) and may form a capacitor.

A first insulating film IL1 may be positioned on the capacitor electrode GE2. The first insulating film IL1 may include an inorganic insulating material such as silicon nitride (SiNx), silicon oxide (SiOx), or silicon oxynitride (SiOxNy). The first insulating film IL1 may be a single-layer or multi-layer structure including at least one selected from the above-listed inorganic insulating materials.

A source electrode SE and a drain electrode DE may be positioned on the first insulating film IL1. The source electrode SE and the drain electrode DE are electrically connected to the source region SO and the drain region DR of the semiconductor layer ACT, respectively, by openings formed in the first insulating film IL1, the second gate insulating film GI2, and the first gate insulating film GI1. Accordingly, the semiconductor layer ACT, the gate electrode GE1, the source electrode SE, and the drain electrode DE form a single transistor TFT. In some embodiments, the transistor TFT may include only a source region and a drain region of the semiconductor layer ACT instead of the source electrode SE and the drain electrode DE.

The source electrode SE and the drain electrode DE may include a metal or metal alloy such as aluminum (Al), copper (Cu), silver (Ag), gold (Au), platinum (Pt), palladium (Pd), nickel (Ni), molybdenum (Mo), tungsten (W), titanium (Ti), chromium (Cr), or tantalum (Ta). The source electrode SE and the drain electrode DE may be a single-layer or multi-layer structures. According to an embodiment, the source electrode SE and the drain electrode DE may be formed of a triple layer including an upper layer, a middle layer, and a lower layer, and the upper layer and the lower layer may include titanium (Ti), and the middle layer may include aluminum (Al).

A second insulating film IL2 may be positioned on the source electrode SE and the drain electrode DE. The second insulating film IL2 covers the source electrode SE and the drain electrode DE. The second insulating film IL2 may planarize the surface of the substrate SUB on which the transistor is provided. The second insulating film IL2 may be an organic insulating film and may include at least one selected from polyimide, polyamide, acrylic resin, benzocyclobutene, and phenol resin.

A plurality of first electrodes E1 may be positioned on the second insulating film IL2. The first electrode E1 may have a single-layer structure including a transparent conductive oxide film or a metal material, or a multi-layer structure including them. The transparent conductive oxide layer may include indium-tin oxide (ITO), poly-ITO, indium-zinc oxide (IZO), indium-gallium-zinc oxide (IGZO), and indium-tin-zinc oxide (ITZO). Metal materials may include silver (Ag), molybdenum (Mo), copper (Cu), gold (Au), and aluminum (Al). In an embodiment, for example, the first electrode E1 may have a triple-layer structure of ITO/Ag/ITO.

The first electrode E1 may be physically and electrically connected to the drain electrode DE through an opening defined in the second insulating layer IL2. Accordingly, the first electrode E1 may receive the output current to be transmitted from the drain electrode DE to a light emitting layer EML.

A pixel insulating layer PDL may be positioned on the first electrode E1 and the second insulating film IL2. The pixel insulating layer PDL may have a pixel opening OP that exposes an upper surface of the first electrode E1. The pixel opening OP may overlap the center of the first electrode E1 and may be spaced apart from the edge of the first electrode E1. The pixel insulating layer PDL may partition a formation location of the light emitting layer EL so that the light emitting layer EL is positioned on the first electrode E1 exposed by the pixel opening OP. The pixel opening OP may define the light emitting area EA of each pixel.

Referring to FIG. 2, the pixel insulating layer PDL may be disposed around the light emitting area EA and may have a lattice shape in a plan view. A width dPDL in a plan view of the pixel insulating layer PDL—that is, the width dPDL of the pixel insulating layer PDL between the adjacent light emitting areas EA1, EA2, and EA3—may be about 5 micrometers (μm) or less. Accordingly, a high-resolution display device may be implemented.

The pixel insulating layer PDL may be an organic insulating film including at least one selected from polyimide, polyamide, acrylic resin, benzocyclobutene, and phenol resin. The pixel insulating layer PDL may include a black pigment.

A partition wall SP may be positioned on the pixel insulating layer PDL. Referring to FIG. 2, the pixel insulating layer PDL may overlap the entire partition wall SP in the third direction DR3, and the partition wall SP may have a lattice shape in a plan view spaced apart from the light emitting area EA. The width dSP of the partition wall SP—that is, the width dSP of the partition wall SP between the adjacent light emitting areas EA—may be in a range of about 1.5 μm to about 3 μm.

The partition wall SP has an upper surface U, a lower surface B in contact with the pixel insulating layer PDL, and a side surface S connected to the upper surface U and the lower surface B. The upper surface U of the partition wall SP may have a smaller area than the lower surface B, and the entire upper surface U may overlap the lower surface B in the third direction DR3. An inclination angle θ1 formed by the side surface S and the lower surface B of the partition wall SP may be about 60° or greater and 90° or less. That is, the inclination angle θ1 of the side surface S of the partition wall SP with respect to the upper surface of the substrate SUB may be about 60° or greater and 90° or less.

A height hSP of the partition wall SP in the third direction DR3 may be in a range of about 1 μm to about 3 μm. Accordingly, a high-resolution display device may be implemented.

The light emitting layer EL may be positioned on the first electrode E1 and the pixel insulating layer PDL. The side surface of the light emitting layer EL is in contact with the side surface S of the partition wall SP, and the partition wall SP may be positioned between a plurality of light emitting layers EL1, EL2, and EL3. The light emitting area EA may correspond to the light emitting layer EL positioned on the first electrode E1 exposed by the pixel opening OP.

In such an embodiment, since the inclination angle of the side surface S of the partition wall SP is 60° or greater, the side surface of the light emitting layer EL may be sealed by the partition wall SP. That is, a light emitting layer EL may be stably implemented by blocking the moisture permeation path on the side surface of the light emitting layer EL by the partition wall SP. That is, since oxygen or moisture does not penetrate the side surface of the light emitting layer EL, the problem of deterioration of the light emitting device may be improved. In addition, a plurality of light emitting layers EL may be clearly distinguished by the partition wall SP, enabling implementation of a high-resolution display device.

The light emitting layer EL may include an organic material that emits red, green, or blue light. The light emitting layer EL, which emits red, green, or blue light, may contain low-molecular or high-molecular organic materials. Although FIG. 3 illustrates the light emitting layer EL as a single layer for convenience of illustration, in practice, the light emitting layer EL may also include auxiliary layers such as an electron injection layer, an electron transfer layer, a hole transfer layer, and a hole injection layer on the top and bottom of the light emitting layer EL, such that the hole injection layer and the hole transfer layer are positioned on the bottom of the light emitting layer EL, and the electron transfer layer and the electron injection layer are positioned on the top of the light emitting layer EL. Depending on the embodiments, the light emitting layer EL may include quantum dots. Quantum dots (hereinafter also referred to as semiconductor nanocrystals) may include group II-VI compounds, group III-V compounds, group IV-VI compounds, group IV elements or compounds, group I-III-VI compounds, group II-III-VI compounds, group I-II-IV-VI compounds, or a combination thereof. The quantum dots may not contain cadmium.

A sacrificial layer SA may be positioned on the light emitting layer EL. The sacrificial layer SA may be in contact with the side surface S of the partition wall SP. The sacrificial layer SA may overlap the pixel insulating layer PDL in the third direction DR3 and be spaced from the light emitting area EA.

The sacrificial layer SA may include an inorganic insulating material including at least one selected from silicon nitride (SiNx), silicon oxide (SiOx), silicon oxynitride (SiOxNy), or a metal oxide such as indium oxide (In), gallium oxide (Ga), zinc oxide (Zn), or aluminum oxide (Al).

A sloper SL may be positioned on the sacrificial layer SA. The sloper SL may contact both opposing side surfaces S of the partition wall SP. The sloper SL may cover the side surface of the partition wall SP and the sacrificial layer SA. Since the inclination angle of the side surface S of the partition wall SP is about 90° or less, the sloper SL may cover the side surface of the partition wall SP without any empty space.

Referring to FIG. 2, the sloper SL may be positioned along both opposing side surfaces S of the partition wall SP and simultaneously surround the light emitting area EA. Additionally, the entire sloper SL may overlap the pixel insulating layer PDL in a plan view and be spaced from the light emitting area EA. A width dSL of the sloper SL in a plan view—that is, the width dSL of the sloper SL that contacts one surface S of the partition wall SP between the adjacent light emitting areas EA—may be about 2 μm or less. Accordingly, a high-resolution display device according to an embodiment may be implemented.

Referring to FIG. 3, the sloper SL has a side surface T on the edge side that does not contact the partition wall SP, and the side surface T of the sloper SL may be inclined toward the partition wall SP. An inclination angle θ2 of the side surface T of the sloper SL with respect to the upper surface of the substrate SUB may be about 45° or less. The inclination angle θ2 may be the inclination angle inside the sloper SL. The side surface T of the sloper SL may be a flat surface or may form a concave curved surface, and in the case of forming a concave curved surface, the inclination angle θ2 of the contact surface with respect to the side surface T with respect to the upper surface of the substrate SUB may gradually decrease as the distance from the substrate SUB decreases.

The sloper SL may include a polymer resin such as polyimide, acrylic, carbazole, or novolak.

A second electrode E2 may be positioned on the partition wall SP and the light emitting layer EL. The second electrode E2 may contact and cover the light emitting layer EL, the partition wall SP, and the sloper SL. Since the inclination angle θ2 of the side surface T of the sloper SL is about 45° or less, the second electrode E2 covering the sloper SL and the light emitting layer EL may have a gentle profile in cross-section. In other words, the sloper SL softens the steep profile so that the second electrode E2 may be formed continuously across the entire surface of the substrate SUB without disconnection or crack. Accordingly, in the display device according to an embodiment, since the second electrode E2 is not disconnected, a problem of increased resistance of the second electrode E2 may be improved.

The second electrode E2 may include or be formed of a transparent conductive layer including indium-tin oxide (ITO), indium-zinc oxide (IZO), indium-gallium-zinc oxide (IGZO), and indium-tin-zinc oxide (ITZO). Additionally, the second electrode E2 may have a translucent characteristic, and the second electrode E2 may form a microcavity together with the first electrode E1. According to the microcavity structure, the spacing and characteristics between the two electrodes allow light of a specific wavelength to be emitted upward, resulting in a red, green, or blue color display. The second electrode E2 may transmit a common voltage to a plurality of pixels.

The first electrode E1, the light emitting layer EL and the second electrode E2 may form a single light emitting device ED which may be a light emitting diode. One of the first electrode E1 and the second electrode E2 may form an anode electrode of the light emitting device ED, and the other of the first electrode E1 and the second electrode E2 may form a cathode electrode. In an embodiment, the first electrode E1 may be the anode electrode of the light emitting device ED and the second electrode E2 may be the cathode electrode.

An encapsulating layer EN may be positioned on the second electrode E2. The encapsulating layer EN may include at least one inorganic film and at least one organic film.

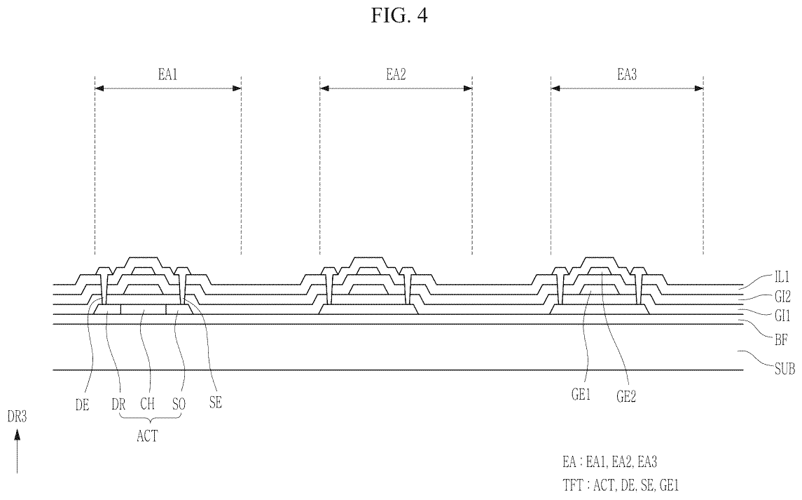

Hereinafter, a manufacturing method of the display device according to an embodiment will be described with reference to FIGS. 4 to 18 together with the drawings described above. FIGS. 4 to 18 are cross-sectional views sequentially illustrating a manufacturing process of a display device according to an embodiment. Any repetitive detailed description of the same configuration as the one described above will be omitted or simplified.

First, referring to FIG. 4, the substrate SUB may include the first light emitting area EA1, the second light emitting area EA2, and the third light emitting area EA3. In a manufacturing process of a display device, the buffer layer BF, the semiconductor layer ACT, the first gate insulating film GI1, the gate electrode GE1, the second gate insulating film GI2, the capacitor electrode GE2, and the first insulating film IL1 are sequentially formed on the substrate SUB. In this process, the transistor TFT as described above may be formed.

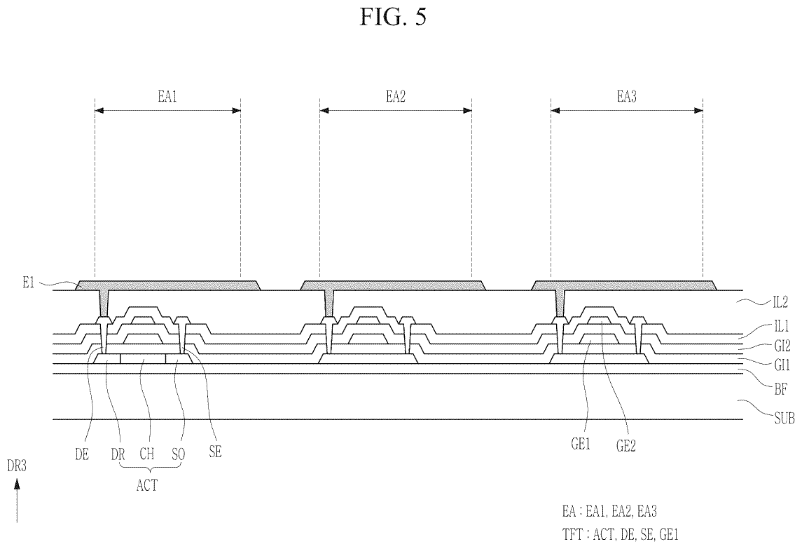

Referring to FIG. 5, a plurality of first electrodes E1 electrically connected to the transistor TFT may be formed on the first insulating film IL1.

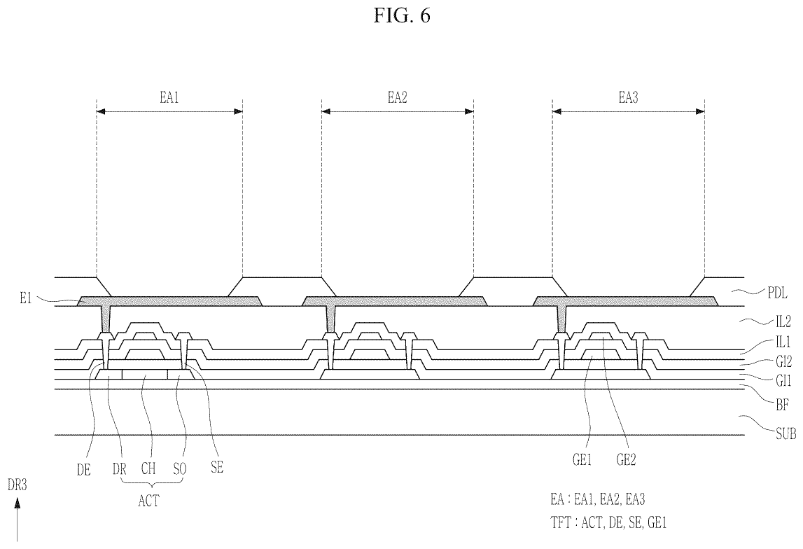

Referring to FIG. 6, the pixel insulating layer PDL may be formed on the first electrode E1 with the pixel opening OP formed therethrough. The pixel opening OP may overlap the center of the first electrode E1 and may be spaced apart from the edge of the first electrode E1. The pixel opening OP may define the light emitting area EA of each pixel.

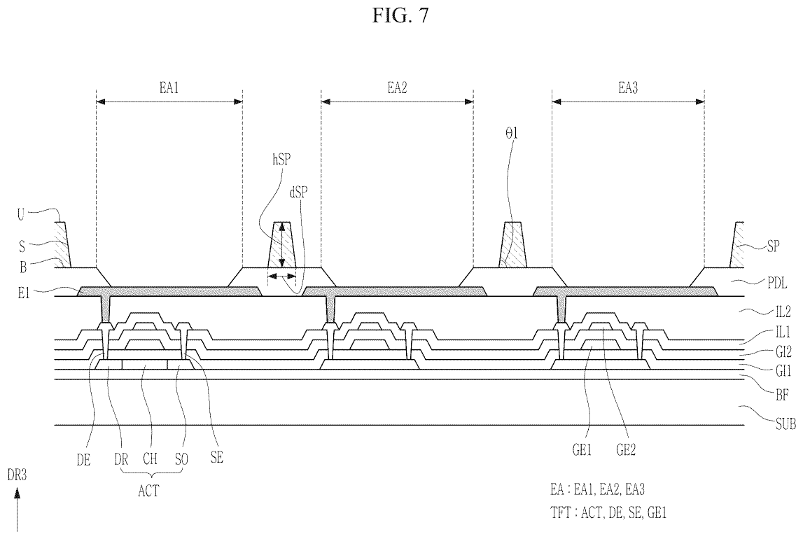

Referring to FIG. 7, the partition wall SP may be formed on the pixel insulating layer PDL. The whole of the partition wall SP may overlap the pixel insulating layer PDL. The width dSP of the partition wall SP may be in a range of about 1.5 μm to about 3 μm. The inclination angle θ1 formed by the side surface S and the lower surface B of the partition wall SP may be about 60° or greater and 90° or less. The height hSP of the partition wall SP may be in a range of about 1 μm to about 3 μm.

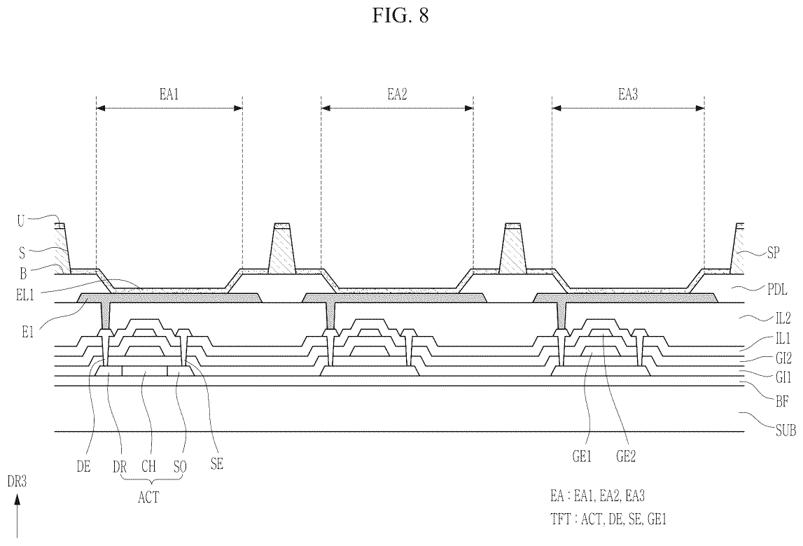

Referring to FIG. 8, the first light emitting layer EL1 may be laminated on the first electrode E1 and the pixel insulating layer PDL. The first light emitting layer EL1 may be laminated on the entire surface of the substrate SUB. In this process, the first light emitting layer EL1 may be in contact with the side surface S of the partition wall SP and may be sealed by the partition wall SP. A layer of the same material as the first light emitting layer EL1 may also be laminated on the partition wall SP, and may be disconnected from the first light emitting layer EL1 of the remaining portion.

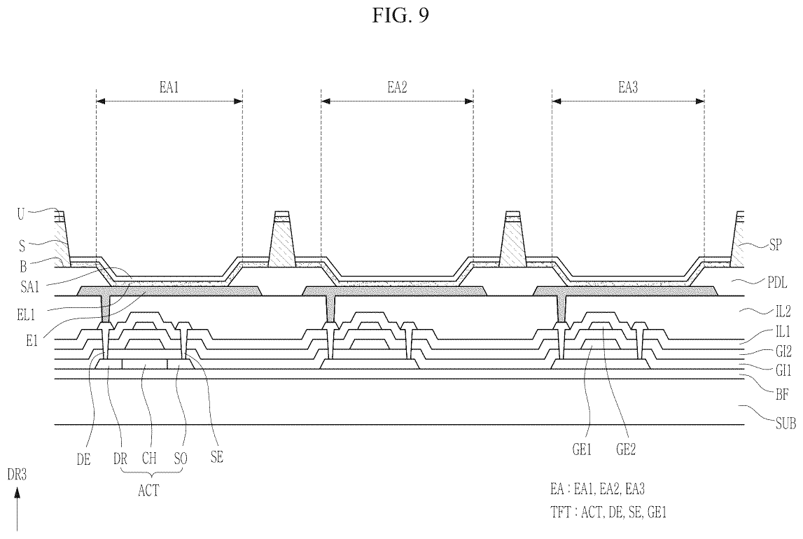

Referring to FIG. 9, a first sacrificial layer SA1 may be laminated on the first light emitting layer EL1. The first sacrificial layer SA1 may be laminated on the entire surface of the substrate SUB including the first light emitting layer EL1. The first sacrificial layer SA1 may be formed in contact with the side surface S of the partition wall SP. The first sacrificial layer SA1 may also be laminated with a layer of a same material as the first sacrificial layer SA1 on the partition wall SP, and may be disconnected from the rest of the first sacrificial layer SA1.

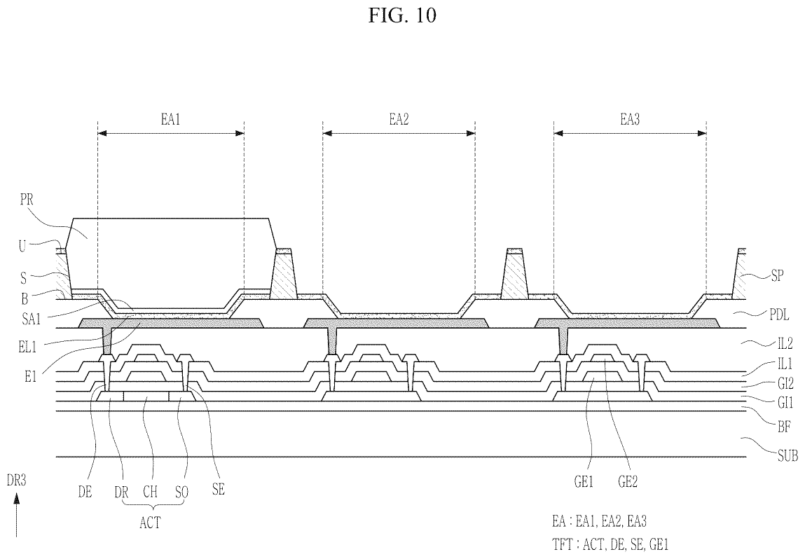

Referring to FIG. 10, the first sacrificial layer SA1 may be patterned to remove portions of the first sacrificial layer SA1 overlapping the second light emitting area EA2 and the third light emitting area EA3. In other words, the first sacrificial layer SA1 may remain only in the inner area of the partition wall SP surrounding the first light emitting area EA1. In an embodiment, for example, a photosensitive film PR may be formed on the first sacrificial layer SA1 to overlap the inner area of the partition wall SP surrounding the first light emitting area EA1, and the first sacrificial layer SA1 may be etched using the photosensitive film PR as a mask. In this case, the first sacrificial layer SA1 may be removed by dry etching or wet etching. The etching process may be performed in an environment where the etching selectivity of the first sacrificial layer SA1 and the first light emitting layer EL1 is about 100 or greater. That is, since the etching rate of the first sacrificial layer SA1 is greater than the etching rate of the first light emitting layer EL1, only the first sacrificial layer SA1 may be selectively removed.

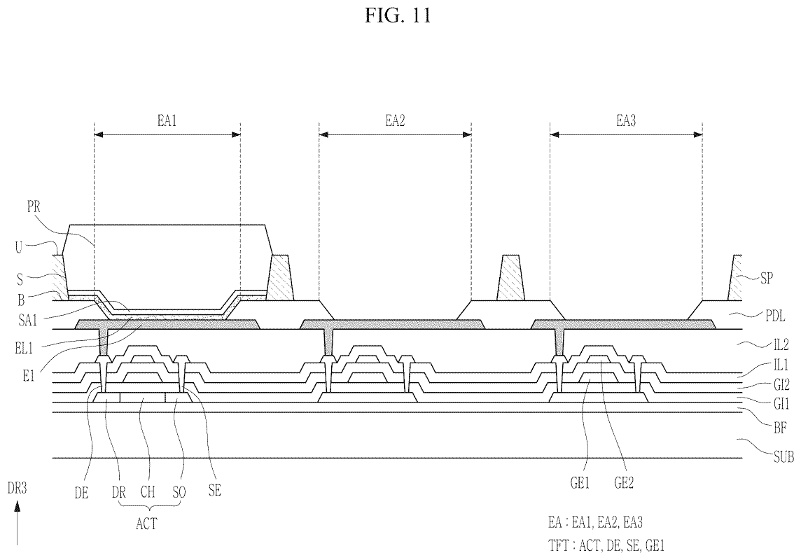

Referring to FIG. 11, the first light emitting layer EL1 may be patterned to remove the first light emitting layer EL1 overlapping the second light emitting area EA2 and the third light emitting area EA3. In other words, the first light emitting layer EL1 may remain only in the inner area of the partition wall SP surrounding the first light emitting area EA1. As shown in FIG. 10, the first light emitting layer EL1 may be etched using the photosensitive film PR as a mask, and may be etched by dry etching or wet etching.

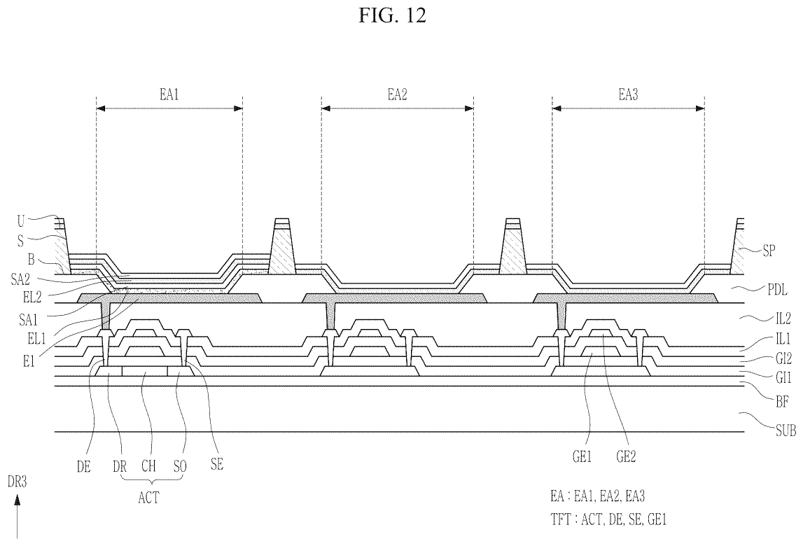

Referring to FIG. 12, the photosensitive film PR illustrated in FIG. 11 may be removed, and the second light emitting layer EL2 and the second sacrificial layer SA2 may be sequentially laminated on the entire surface of the substrate SUB. In this process, the second light emitting layer EL2 and the second sacrificial layer SA2 may be laminated on the first sacrificial layer SA1 in the first light emitting area EA1.

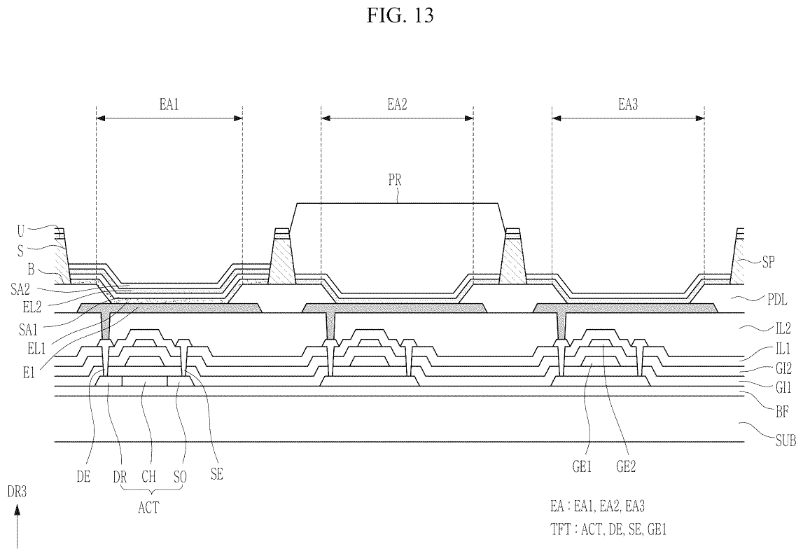

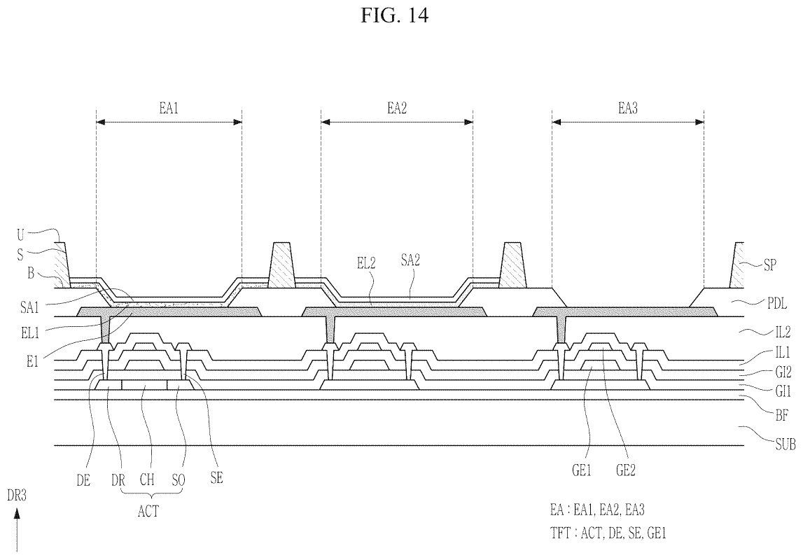

Referring to FIGS. 13 and 14, the second sacrificial layer SA2 and the second light emitting layer EL2 may be sequentially patterned so that the second light emitting layer EL2 and the second sacrificial layer SA2 remain only inside the partition wall SP surrounding the second light emitting area EA2. In an embodiment, for example, the photosensitive film PR as shown in FIG. 13 may be formed to overlap the inner area of the partition wall SP surrounding the second light emitting area EA2, and the second sacrificial layer SA2 and the second light emitting layer EL2 may be sequentially etched using the photosensitive film PR as a mask. In this process, since the etching selectivity of the second light emitting layer EL2 and the first sacrificial layer SA1 is high, only the second light emitting layer EL2 may be selectively removed from the first light emitting area EA1.

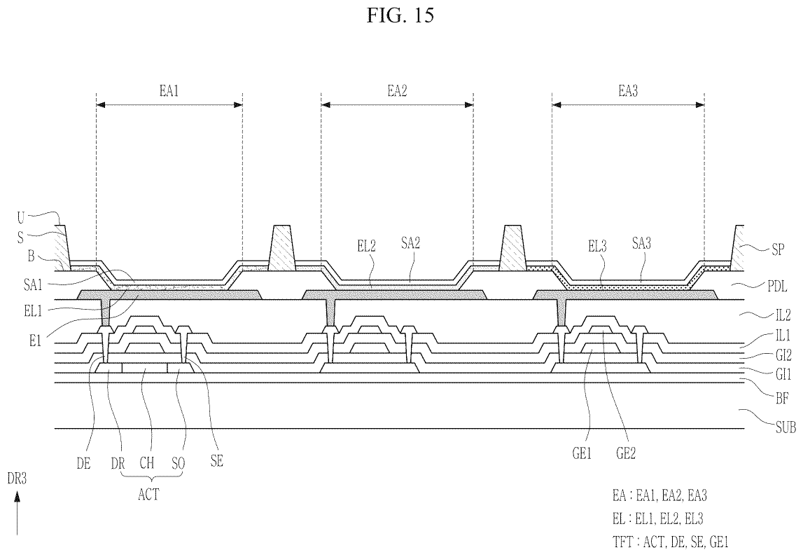

Referring to FIG. 15, a third light emitting layer EL3 and a third sacrificial layer SA3 may be formed inside the partition wall SP surrounding the third light emitting area EA3. Similar to the patterning process of the first light emitting layer EL1 and the first sacrificial layer SL1 or the patterning process of the second light emitting layer EL2 and the second sacrificial layer SL2 shown in FIGS. 8 to 14, the third light emitting layer EL3 and the third sacrificial layer SA3 may be laminated on the entire surface of the substrate SUB, and then the third sacrificial layer SA3 and the third light emitting layer EL3 may be etched.

The display device according to an embodiment may easily form separate light emitting layers EL1, EL2, and EL3 for each light emitting area EA1, EA2, and EA3 by using the partition wall SP according to an embodiment without using a fine metal mask when laminating the light emitting layers EL1, EL2, and EL3, thereby reducing the manufacturing cost of the display device and making it easy to implement a high-resolution display device.

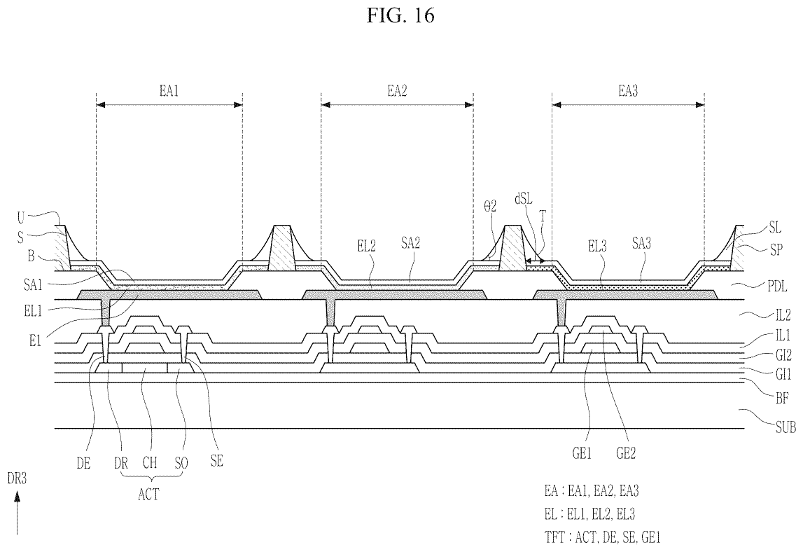

Referring to FIG. 16, the sloper SL may be formed to be in contact with the side surface of the partition wall SP on the first sacrificial layer SA1, the second sacrificial layer SA2, and the third sacrificial layer SA3. In an embodiment, for example, a polymer resin may be coated along the side surface of the partition wall SP and cured to form the sloper SL. Depending on embodiments, a polymer resin is applied to the entire surface of a substrate SUB, a photosensitive film is formed in an area spaced apart from the light emitting areas EA, and then the sloper SL may be formed using the photosensitive film as a mask. Since the inclination angle of the side surface S of the partition wall SP is about 90° or less, the sloper SL may cover the side surface of the partition wall SP without any empty space.

The width dSL of the sloper SL may be about 2 μm or less. The side surface T of the sloper SL is inclined toward the partition wall SP, and the inclination angle θ2 formed by the side surface T of the sloper SL with respect to the upper surface of the substrate SUB may be about 45° or less.

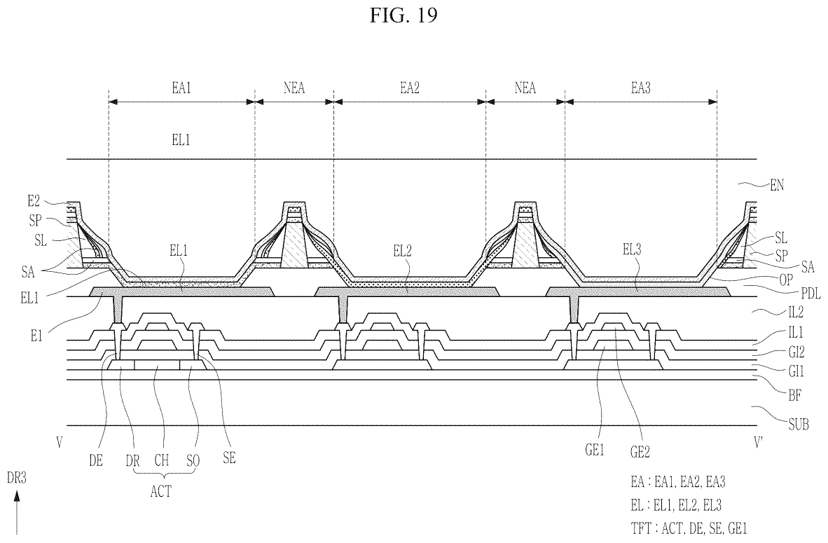

Referring to FIG. 16, in the manufacturing method of the display device according to an embodiment, the sloper SL may be formed after the first light emitting layer EL1, the second light emitting layer EL2, and the third light emitting layer EL3 are formed. However, the present disclosure is not limited thereto, and the sloper SL according to another embodiment may be formed after the lamination process of the first sacrificial layer SA1 of FIG. 9, or may be formed after the lamination process of the second sacrificial layer SA2 of FIG. 12. In other words, the sloper SL may be formed after laminating at least one of the first light emitting layer EL1 and the first sacrificial layer SA1, the second light emitting layer EL2 and the second sacrificial layer SA2, and the third light emitting layer EL3 and the third sacrificial layer SA3. The structure thereof will be described later with reference to FIG. 19.

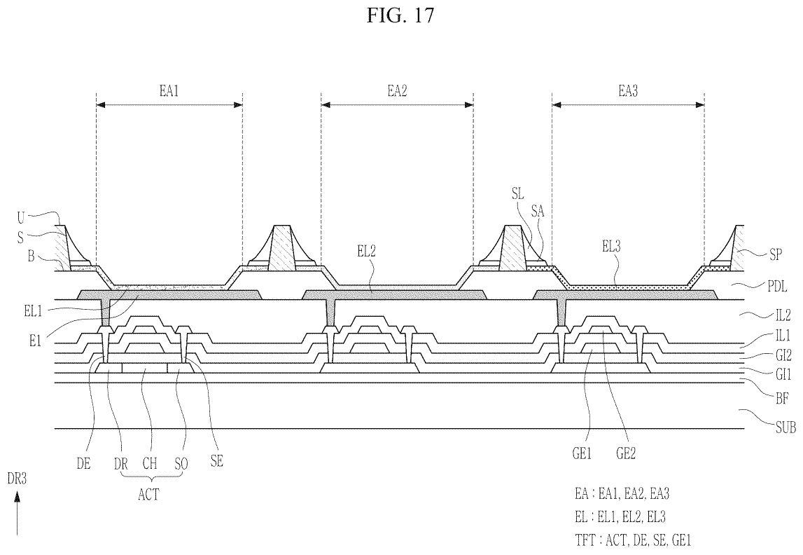

Referring to FIG. 17, the sacrificial layer SA may be removed using the sloper SL as a mask. In FIG. 17, the sacrificial layer SA represents the entire patterned first sacrificial layer SA1, second sacrificial layer SA2, and third sacrificial layer SA3 described above. In an embodiment, for example, the first sacrificial layer SA1, the second sacrificial layer SA2, and the third sacrificial layer SA3 may be etched using the sloper SL as a mask without a separate photosensitive film. Accordingly, the sacrificial layer SA overlapping the light emitting area EA may be removed.

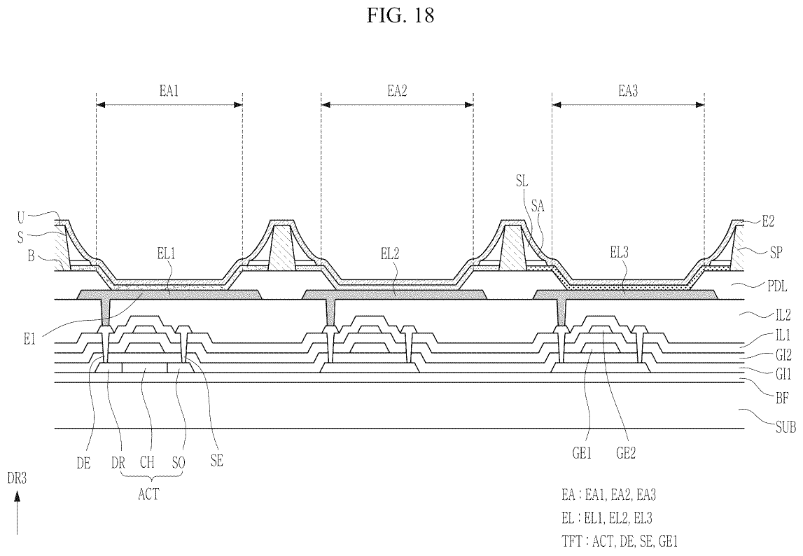

Referring to FIG. 18, the second electrode E2 may be formed on the light emitting layer EL, the partition wall SP, and the sloper SL. According to an embodiment, the second electrode E2 may be formed continuously on the entire surface of the substrate SUB by the sloper SL without breaking. In such an embodiment, since the inclination angle θ2 of the sloper SL is about 45° or less, the second electrode E2 covering the sloper SL and the light emitting layer EL may have a gentle shape or profile in cross-section. Accordingly, in the display device according to an embodiment, the problem of increased resistance of the second electrode E2 may be improved because the second electrode E2 is not broken.

Below, the display area of the display device according to an embodiment will be described with reference to FIG. 19 together with the drawings described above. FIG. 19 is a cross-sectional view illustrating a portion of a display area in a display device according to an embodiment. The display device shown in FIG. 19 is substantially the same as the display device shown in FIG. 3 except for the structure of the light emitting layer EL and the sacrificial layer SA, any repetitive detailed description of the same or like configurations as those described above will be omitted.

Referring to FIG. 19, in an embodiment, the plurality of light emitting layers EL may include the first light emitting layer EL1, the second light emitting layer EL2, and the third light emitting layer EL3 which emit different colored lights, respectively. The first light emitting layer EL1 may be positioned in the first light emitting area EA1, the second light emitting layer EL2 may be positioned in the second light emitting area EA2, and the third light emitting layer EL3 may be positioned in the third light emitting area EA3.

In the non-light emitting area NEA, at least one of the plurality of light emitting layers EL1, EL2, and EL3 may be positioned under the sloper SL in the third direction DR3, and the rest of the plurality of light emitting layers EL may be positioned on the sloper SL. FIG. 19 shows an embodiment where in the non-emitting area NEA, the first light emitting layer EL1 is positioned under the sloper SL, and the second light emitting layer EL2 and the third light emitting layer EL3 are positioned on the sloper SL. At least one of the plurality of light emitting layers EL1, EL2, and EL3 may remain on the partition wall SP.

Referring to FIG. 19, the side surface of the first light emitting layer EL1 may be in contact with the side surface of the partition wall SP. The side surfaces of the second light emitting layer EL2 and the third light emitting layer EL3 may be in contact with the side surfaces of the sloper SL or with the second light emitting layer EL2 or the third light emitting layer EL3 remaining on the upper surface of the partition wall SP. Accordingly, the side surfaces of the first light emitting layer EL1, the second light emitting layer EL2, and the third light emitting layer EL3 may be sealed to block moisture permeation paths. Accordingly, the problem of degradation of the light emitting device may be improved because moisture or oxygen does not penetrate the side surfaces of the light emitting layers EL1, EL2, and EL3.

In the non-light emitting area NEA, the sacrificial layer SA may be positioned between the first light emitting layer EL1 and the sloper SL. The sacrificial layer SA may be further positioned between the second light emitting layer EL2 and the third light emitting layer EL3 positioned on the sloper SL.

The sloper SL may be formed after laminating at least one of the first light emitting layer EL1, the second light emitting layer EL2, and the third light emitting layer EL3. FIG. 19 shows that the sloper SL is formed after the lamination process of the first light emitting layer EL1 and the first sacrificial layer SA1 shown in FIG. 9. Specifically, after laminating the first light emitting layer EL1 and the first sacrificial layer SA1, the sloper SL may be formed, and the first sacrificial layer SA1 and the first light emitting layer EL1 positioned in the remaining light emitting area may be removed. Then, as in FIGS. 12 to 15, the second light emitting layer EL2 may be formed in the second light emitting area EA2, and the third light emitting layer EL3 may be formed in the third light emitting area EA3.

The display device according to an embodiment may have a side surface of the light emitting layer in contact with the partition wall, so that the moisture permeation path of the side surface of the light emitting layer is blocked, thereby improving the problem of degradation of the light emitting device. In addition, since the inclination angle of the side surface of the partition wall is about 60° or greater, the plurality of light emitting layers are clearly distinguished by the partition wall, so that a high-resolution display device may be implemented. Furthermore, since the inclination angle of the sloper adjacent to the side surface of the partition wall is about 45° or less, the second electrode covering the sloper is not broken, so the resistance increase problem may be improved.

The display device according to an embodiment may be applied to various electronic devices. The electronic device according to an embodiment includes the above-described display device, and may further include a module or device having other functions in addition to the display device.

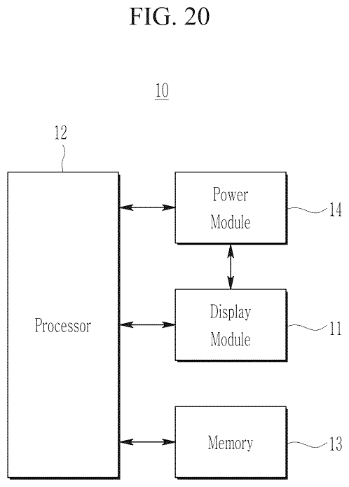

FIG. 20 is a block diagram of an electronic device according to an embodiment. Referring to FIG. 20, an electronic device 10 according to an embodiment may include a display module 11, a processor 12, a memory 13 and a power module 14.

The processor 12 may include at least one selected from a central processing unit (CPU), an application processor (AP), a graphic processing unit (GPU), a communication processor (CP), an image signal processor (ISP), and a controller.

Data information necessary for the operation of the processor 12 or the display module 11 may be stored in the memory 13. When the processor 12 executes an application stored in the memory 13, an image data signal and/or an input control signal is transmitted to the display module 11, and the display module 11 may process the received signal and output an image through the display screen.

The power module 14 may include a power supply module, such as a power adapter or a battery device, and a power conversion module that converts power supplied by the power supply module to generate power used for the operation of the electronic device 10.

At least one of the components of the electronic device 10 described above may be included in the display device according to the embodiments. Additionally, some of the individual modules functionally included within a module may be included within the display device, while others may be provided separately from the display device. In an embodiment, for example, the display device may include the display module 11, and the processor 12, the memory 13, and the power module 14 may be provided in the form of other devices within the electronic device 10 other than the display device.

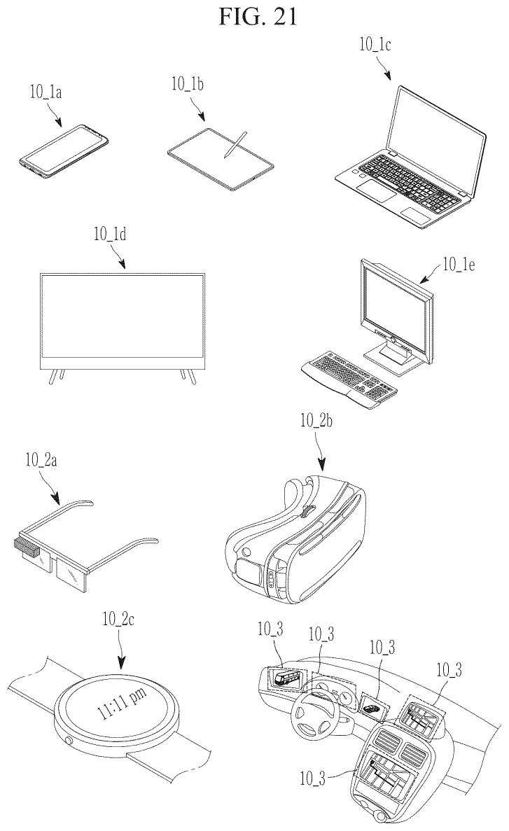

FIG. 21 is a schematic diagram of an electronic device according to various embodiments.

Referring to FIG. 21, various electronic devices to which display devices according to embodiments are applied may include electronic devices for displaying images, such as a smartphone 10_1a, a tablet personal computer (PC) 10_1b, a laptop 10_1c, a television (TV) 10_1d, and a desk monitor 10_1e. In addition, the electronic devices may include a wearable electronic device including a display module such as smart glasses 10_2a, a head mounted display 10_2b, a smartwatch 10_2c, and the like, a vehicle electronic device 10_3 including a display module or display device such as a center information display (CID), a room mirror display, and the like positioned on a dashboard, a center fascia, or an instrument panel of an automobile.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device, comprising:
a substrate;
a plurality of first electrodes disposed on the substrate;
a pixel insulating layer disposed on the first electrode, wherein a pixel opening is defined through the pixel insulating layer;
a partition wall disposed on the pixel insulating layer;
a light emitting layer disposed on the first electrode and the pixel insulating layer;
a sloper disposed on the pixel insulating layer to be adjacent to a side surface of the partition wall; and
a second electrode disposed on the light emitting layer and the partition wall,
wherein an inclination angle of the side surface of the partition wall with respect to an upper surface of the substrate is about 60° or greater and about 90° or less, and
an inclination angle of a side surface of the sloper with respect to the upper surface of the substrate is about 45° or less.

2. The display device of claim 1, wherein
a side surface of the light emitting layer is in contact with the side surface of the partition wall.

3. The display device of claim 1, wherein a width of the partition wall is in a range of about 1.5 μm to about 3 μm.

4. The display device of claim 1, wherein a height of the partition wall is in a range of about 1 μm to about 3 μm.

5. The display device of claim 1, wherein
the sloper covers the side surface of the partition wall and extends along an edge of the partition wall in a plan view.

6. The display device of claim 5, wherein a width of the sloper in the plan view is about 2 μm or less.

7. The display device of claim 5, wherein
the sloper is disposed on the light emitting layer and overlaps an edge of the light emitting layer in the plan view.

8. The display device of claim 1, further comprising a sacrificial layer disposed between the light emitting layer and the sloper.

9. The display device of claim 8, wherein the sacrificial layer is in contact with the side surface of the partition wall.

10. The display device of claim 8, wherein
the light emitting layer comprises a first light emitting layer including a portion disposed in the pixel opening, and
the sacrificial layer is disposed between the sloper and the first light emitting layer.

11. The display device of claim 8, wherein
the light emitting layer comprises a first light emitting layer including a portion disposed in the pixel opening and a second light emitting layer not overlapping the pixel opening, and
the sacrificial layer is disposed between the sloper and the second light emitting layer.

12. The display device of claim 1, wherein
the second electrode is in contact with the light emitting layer, an upper surface of the partition wall, and the side surface of the sloper.

13. The display device of claim 1, wherein
the pixel insulating layer overlaps an edge of the first electrode in a plan view.

14. The display device of claim 13, wherein
the pixel insulating layer overlaps an entire portion of the partition wall in the plan view.

15. The display device of claim 13, wherein
the pixel insulating layer overlaps an entire portion of the sloper in the plan view.

16. The display device of claim 13, wherein a width of the pixel insulating layer in the plan view is about 5 μm or less.

17. A manufacturing method of a display device, the manufacturing method comprising:
preparing a substrate;
forming a plurality of first electrodes on the substrate;
forming a pixel insulating layer on the first electrode, wherein a pixel opening is formed through the pixel insulating layer;
forming a partition wall on the pixel insulating layer,
forming a first light emitting layer on the first electrode and the pixel insulating layer;
forming a sloper on the partition wall to contact a side surface of the partition wall; and
forming a second electrode on the first light emitting layer and the partition wall,
wherein an inclination angle of the side surface of the partition wall with respect to an upper surface of the substrate is about 60° or greater and about 90° or less, and
an inclination angle of the side surface of the sloper with respect to the upper surface of the substrate is about 45° or less.

18. The manufacturing method of the display device of claim 17, wherein
the substrate comprises a first light emitting area and a second light emitting area,
after the forming the first light emitting layer and before the forming the sloper, the manufacturing method of the display device further comprises:
laminating a first sacrificial layer on the first light emitting layer;
removing portions of the first sacrificial layer and the first light emitting layer in a region excluding an inside of the partition wall surrounding the first light emitting area;
laminating a second light emitting layer on an entire surface of the substrate;
laminating a second sacrificial layer on the second light emitting layer; and
removing portions of the second sacrificial layer and the second light emitting layer disposed in a region excluding an inside of the partition wall surrounding the second light emitting area.

19. The manufacturing method of the display device of claim 18, further comprising:
removing portions of the first sacrificial layer and the second sacrificial layer, which do not overlap the sloper, to expose the first light emitting layer and the second light emitting layer.

20. An electronic device, comprising:
a display device and a processor,
wherein the display device comprises:
a substrate;
a plurality of first electrodes disposed on the substrate;
a pixel insulating layer disposed on the first electrode, wherein a pixel opening is defined through the pixel insulating layer;
a partition wall disposed on the pixel insulating layer;
a light emitting layer disposed on the first electrode and the pixel insulating layer;
a sloper disposed on the pixel insulating layer to be adjacent to a side surface of the partition wall; and
a second electrode disposed on the light emitting layer and the partition wall,
wherein an inclination angle of the side surface of the partition wall with respect to an upper surface of the substrate is about 60° or greater and 90° or less, and
an inclination angle of the side surface of the sloper with respect to the upper surface of the substrate is about 45° or less.
